(19) United States
(12) Patent Application Publication
(10) Pub. No.: US 2026/0019165 A1
(43) Pub. Date: Jan. 15, 2026

(54) Optical Communication Bar

(71) Applicant: Apple Inc., Cupertino, CA (US)

(72) Inventor: Sanjay Dabral, Cupertino, CA (US)

(21) Appl. No.: 18/767,877

(22) Filed: Jul. 9, 2024

(51) Int. Cl. H04B 10/80; H01S 5/183

(52) U.S. Cl. CPC H04B 10/801; H01S 5/183

(57) ABSTRACT

Electronic assemblies and systems are described in which optical communication bars are incorporated to provide optical interconnect paths between various components, local or remote. The optical communication bars can include photonic waveguides formed using a variety of suitable techniques and may include photonic wires (e.g., bundled fiber or formed using 3D multi-photon write, holographic write, micro-pen write, direct optical wire bonding, or a mix), or index defined patterns forms using techniques such as nano imprint (embossing), lithography, etc.

### BACKGROUND

### Field

Embodiments described herein relate to photonics, and more particularly to optical interconnects.

### Background Information

Optical interconnects are an integral part of today's compute infrastructure including both within and between data centers where racks are fully connected to each other with optical interconnects, as well as over long-haul communications, including transoceanic communications.

### SUMMARY

Electronic assemblies and systems, and methods as manufacture are described in which optical communication bars are incorporated to provide optical interconnect paths between various components, local or remote. The optical communication bars can include photonic waveguides formed using a variety of suitable techniques and may include photonic wires (e.g., bundled fiber or formed using 3D multi-photon write, holographic write, micro-pen write, direct optical wire bonding, or a mix), or index defined patterns forms using techniques such as nano imprint (embossing), lithography, etc.

In an embodiment, an electronic assembly includes a first die with a first core region, a second die with a second core region, and an optical communication bar that provides a path between the first core region and the second core region. The optical communication bar can include additional optical paths between one or more of the dies and a connector(s) for external optical connection with the electronic assembly.

For example, the optical communication bar can be mounted onto a routing layer side-by side with the first and second dies, or the optical communication bar can be integrated within or underneath a routing layer onto which the dies are mounted in a 3D configuration. The optical communication bars can include a variety of components for modular assembly. For example, the optical communication bar can include a first optical engine including a first controller logic and first optical transmitter, a second optical engine including a second controller logic and second optical detector, and one or more molding compound layers encapsulating the first optical engine, the second optical engine, and the optical path where the optical path extends between the first optical transmitter and the second optical detector. The one or more molding compound layers can include separate molding compound layers that separately encapsulate the first and second optical engines, and the optical path may span between the separate molding compound layers.

Alternatively, a single molding compound layer can encapsulate the optical engines and the optical path. In one variation an electrical interfacing bar can also be embedded in the single molding compound layer to provide electrical die-to-die routing between the dies. In yet another configuration optical engines can be mounted onto an interfacing bar that includes a waveguide.

The optical engines in accordance with embodiments can be stacked assemblies. For example, a first optical transmitter can be bonded on top of a first controller logic. For example, this can be with hybrid bonding or other bonding. Similarly, a second optical detector can be hybrid bonded with a second controller logic.

Electronic systems are also described in which optical paths are provided between multiple electronic assemblies. In an embodiment an electronic system includes a first electronic assembly including a first routing substrate and a first optical communication bar connected with the first routing substrate, and a second electronic assembly including a second routing substrate and a second optical communication bar connected with the second routing substrate. The first optical communication bar can include a first optical engine, a first waveguide, and a first connector coupled with the first waveguide, while the second optical communication bar includes a second optical engine, a second waveguide, and a second connector coupled with the second waveguide. In accordance with embodiments a fiber bundle can be coupled with the first connector and the second connector.

In an exemplary configuration, a first die and a second die are connected with the first routing substrate. The first optical communication bar can additionally include a local waveguide connected between the first die and the second die. The fiber bundle may additionally extend a longer distance than the local waveguide. The optical communication bar may additionally include a first a first internal optical-to-electrical (OE) converter coupled with the local waveguide, a first internal electrical-to-optical (EO) converter coupled with the local waveguide, and a first external EO converter coupled with the first waveguide, where the first internal EO converter includes a micro light emitting diode (LED) or nano LED, and the first external EO converter comprises a vertical-cavity surface-emitting laser (VCSEL).

### BRIEF DESCRIPTION OF THE DRAWINGS

FIG. 1 is a trend graph that generalizes energy requirements over interconnection distance for both electrical and optical interconnects.

FIG. 2A is a schematic cross-sectional side view illustration of an electronic assembly with a combination of electrical and optical paths in accordance with an embodiment.

FIG. 2B is a schematic top view illustration of an electronic assembly with a combination of electrical and optical paths in accordance with an embodiment.

FIG. 3A is a schematic top view illustration of a 3D electronic assembly with a combination of electrical and optical communication bars in accordance with an embodiment.

FIG. 3B is a schematic cross-sectional side view illustration of a 3D electronic assembly along section B-B of FIG. 3A in accordance with an embodiment.

FIG. 3C is a schematic cross-sectional side view illustration of a 3D electronic assembly along section B-B of FIG. 3A in accordance with an embodiment.

FIG. 4A is a schematic top view illustration of a side-by-side electronic assembly with a combination of electrical and optical communication bars in accordance with an embodiment.

FIG. 4B is a schematic cross-sectional side view illustration of a side-by-side electronic assembly along section B-B of FIG. 4A in accordance with an embodiment.

FIG. 5A is a schematic top plan view illustration of a plurality of optical paths formed across a wafer in accordance with an embodiment.

FIG. 5B is a schematic top plan view illustration of a plurality of optical paths formed across a panel in accordance with an embodiment.

FIG. 6A is a schematic top plan view illustration of an optical communication bar including linear optical paths in accordance with an embodiment.

FIG. 6B is a schematic top plan view illustration of an optical communication bar including gridded optical paths in accordance with an embodiment.

FIG. 7 is a schematic cross-sectional side view illustration of an optical engine in accordance with an embodiment.

FIG. 8A is a schematic cross-sectional side view illustration of an optical engine including a plurality of discrete diodes or VCSELs accordance with an embodiment.

FIG. 8B is a schematic cross-sectional side view illustration of an optical engine including a plurality of joined diodes in accordance with an embodiment.

FIG. 9 is a schematic cross-sectional side view illustration of an optical communication bar with wholly contained optical path in accordance with an embodiment.

FIG. 10 is a schematic cross-sectional side view illustration of an optical path spanning between multiple optical communication bars in accordance with an embodiment.

FIG. 11 is a schematic cross-sectional side view illustration of an optical communication bar including optical and electrical interconnect paths in accordance with an embodiment.

FIG. 12 is a schematic cross-sectional side view illustration of an optical communication bar including a waveguide and flexible encapsulation in accordance with an embodiment.

FIG. 13 is a schematic cross-sectional side view illustration of an optical communication bar including a holographic waveguide and flexible encapsulation in accordance with an embodiment.

FIG. 14 is a schematic cross-sectional side view illustration of an optical communication bar including wire bonded optical engines in accordance with an embodiment.

FIG. 15A is schematic cross-sectional side view illustration of an optical communication bar including optical engines hybrid bonded to an interfacing bar in accordance with an embodiment.

FIG. 15B is schematic cross-sectional side view illustration of an optical communication bar including optical engines flip chip bonded to an interfacing bar in accordance with an embodiment.

FIGS. 16A-16D are cross-sectional side view illustrations for a sequence of forming a waveguide over embedded optical engines in accordance with an embodiment.

FIGS. 17A-17F are cross-sectional side view illustrations for sequences of forming waveguides over optical engines and embedding both in accordance with embodiments.

FIG. 18 is a schematic cross-sectional side view illustration of an electronic system including optical communication bars with connectors for external optical communication in accordance with an embodiment.

FIG. 19A is a schematic cross-sectional side view illustration of an electronic system with optical communication bars including optical engines for short reach optical communication and connectors for external optical communication in accordance with embodiments.

FIG. 19B is a schematic top view illustration of an electronic system with optical communication bars including optical engines for short reach optical communication and connectors for external optical communication in accordance with embodiments.

### DETAILED DESCRIPTION

Embodiments describe electronic assemblies in which one or more optical communication bars are integrated to provide an optical path across a single die or package, or between multiple dies or packages. The optical communication bars can be rigid or flexible. Connectors can be integrated with the optical communication bars for longer reach applications.

The optical communication bars in accordance with embodiments can provide the option to integrate optical sub-components (e.g., electrical-to-optical, optical-to-electrical, waveguide, etc.) separately, and then to integrate with an electronic assembly. The optical communication bars in accordance with embodiments can be modularized where sub-components are interchangeable, facilitating cost-efficiency while being able to match communication requirements (e.g., bandwidth, power, latency).

Photonic coupling with the optical communication bars may include photonic waveguides coupled with optical engines that include one or more converters such as electrical-to-optical (EO) converters and optical-to-electrical (OE) converters and controller logic (also referred to as conversion electronics). The photonic waveguides can be formed using a variety of suitable techniques and may include photonic wires (e.g., bundled fiber or formed using additive manufacturing such as 3D multi-photon write, holographic write, micro-pen write, direct optical wire bonding, or a mix), or index defined patterns formed using techniques such as nano imprint (embossing), lithography, etc. Additional optics for coupling optical transceivers (emitters) and optical receivers (detectors) with the photonic waveguides, such as lenses, grating couplers, mirrors, prisms, optical vias, etc. can also be formed using similar techniques. The controller logic can include the necessary driving circuitry for the converter(s), and can optionally include additional components such as multiplexers, demultiplexers, modulators, buffers, etc. An EO converter may include any suitable optical transmitter such as laser, light emitting diode, or other light source. An OE converter may include an optical receiver such as a photodetector (avalanche photodiode, p-i-n photodiode, etc.). One or more optical repeater structures may additionally be included in the optical paths to receive, amplify, and then re-transmit the optical signals. One example is an optical amplifier (e.g. semiconductor optical amplifier). Other repeaters may be electrical/optical that can be integrated into active silicon connected to the optical paths with a variety of features such as logic, flops, cache, memory compressors and decompressors, controllers, local processing elements, etc.

The optical paths produced by the waveguides or photonic wires may be rigid or flexible. In an exemplary embodiment, waveguides are formed of a suitable material, such as oxide or nitride, that is readily integrated into semiconductor device fabrication and packaging.

The optical paths in accordance with embodiments can range from very short, to long reach, to extra-long reach. For example, shorter length applications can be intra-die or inter-die connections, such as die-edge to die-edge connections, such as 20 mm or less. Longer reach applications can include intra-die or inter-die connections such as die-core to die-core (core-to-core) connections. Exemplary lengths may be 20 mm-100 mm. Such longer reach applications may provide lower latency and energy requirements compared to electrical interconnects, particularly for high wiring density. Still longer reach applications, such as 50 mm to 10 m can include electrical and optical communication mixing, with connection possibilities not being limited to die peripheries, and can be from the die core point of use. Even longer reach applications, such as 1+m-1+km may utilize higher power optical emitters such as lasers with modulators and multiplexers.

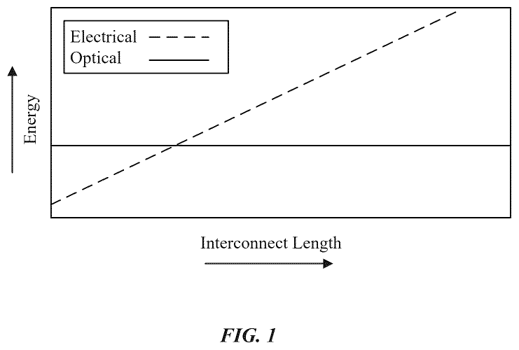

Referring now to FIG. 1 a trend graph is shown that generalizes energy requirements over interconnection distance for both electrical and optical interconnects. As shown in this trend graph energy increases with electrical interconnect distance, while energy requirements for optical interconnects can be relatively constant. The optical interconnect energy requirements may depend upon components of the optical bar however, such as emitter and detector types, and whether or not modulators, multiplexers and cooling systems are to be integrated. As can be seen, above a critical distance, optical interconnect energy requirements can be substantially less than that of electrical interconnect requirements. Below such a critical distance, energy requirements may be more favorable for electrical interconnects, which can be both passive and active interconnects. For example, active electric interconnects may span further distances and reduce latency. However, there are still limits to efficient electrical communication. Additionally, as technology continues to trend to higher bandwidth and data rate applications with higher latency thresholds metal interconnects can reach their practical limits, with photonic coupling being a viable alternative despite the minimum energy requirements.

Emitter and detector types can also be selected based on reach (interconnect distance) and energy requirements. For example, micro light emitting diodes (μLEDs or micro LEDs), nano LEDs, μVCSEL, or nano lasers can be used for optical emitters for shorter reach applications (e.g., less than 10 m), while lasers (e.g., VCSEL, or laser modulator systems) can be used for much larger reaches. Micro LEDs, as well as nano LEDs, can also be operated at lower energy levels since they may be operated at peak efficiencies as opposed to lasers which are operated at higher (and saturated) current densities and energy levels. Lasers may also be used for higher bandwidths than micro LEDs, though this can come at a higher cost and circuit complexity, as well as inclusion of additional sub-components such as an optical switch, modulator and multiplexor (and demultiplexer).

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “above”, “over”, “to”, “between”, “spanning” and “on” as used herein may refer to a relative position of one layer with respect to other layers. One layer “above”, “over”, “spanning” or “on” another layer or bonded “to” or in “contact” with another layer may be directly in contact with the other layer or may have one or more intervening layers. One layer “between” layers may be directly in contact with the layers or may have one or more intervening layers.

In one aspect embodiments describe electronic assemblies and optical communication bars that can provide modularity to the electronic assemblies where optical sub-components can be packaged together within the optical communication bars. Furthermore, the optical communication bars can be integrated into the electronic assemblies in a 3D and/or side-by-side configuration with the dies that are being connected. The optical communication bars may additionally support both electrical and optical interconnection.

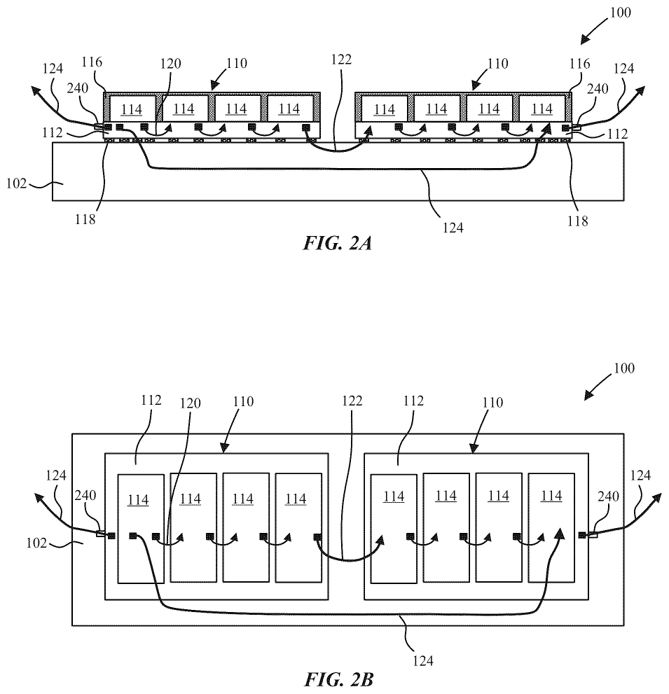

Referring now to FIGS. 2A-2B, FIG. 2A is a schematic cross-sectional side view illustration of an electronic assembly with a combination of electrical and optical paths in accordance with an embodiment; FIG. 2B is a schematic top view illustration of an electronic assembly with a combination of electrical and optical paths in accordance with an embodiment. As shown, the electronic assembly may be a module 100 including a module substrate 102, such as a printed circuit board (PCB), and a plurality of packages 110 mounted onto the circuit board, for example with solder bumps 118. Each package can include a package substrate 112, a plurality of dies 114 on the package substrate, and optionally a molding compound layer 116 encapsulating the plurality of dies 114 on the package substrate 112. The package substrate 112 can be a variety of different structures and formed in a variety of manners. For example, the package substate can be a separately formed interposer, etc. or fanout routing layers formed over the dies 114. The package substrate 112 in accordance with embodiments may include one or more optical communication bars as described herein or be an optical communication bar in itself. The substrates in accordance with embodiments, inclusive of the module substrate 102 and package substrate 112, can range from PCB substrates, to multi-chip-module (MCM) substrates, glass, silicon, combinations of rigid or flexible fibers, etc. The dies 114 may be the same type of dies or different types. The various dies 114 in accordance with embodiments described herein can include an assembly of different components, can be heterogenous, and can be hierarchically arranged. Exemplary dies can include system-on-chip (SOC), graphics processing unit (GPU), central processing unit (CPU), artificial intelligence (AI), machine learning logic, radiofrequency (RF) baseband processor, radio-frequency (RF) antenna, signal processors, power management integrated circuit (PMIC), logic, memory (e.g., high bandwidth memory, etc.), input output (I/O), biochips, etc. Reference to “core regions” therein in accordance with embodiments may be in reference to a particular intellectual property block (IP block) that processes significant amounts of data relative to other regions of the die. Often a core region may be an internal region as opposed to edge region of the die.

As shown in the schematic illustrations, adjacent dies 114 can be connected with interconnect paths 120. For example, these may be electrical interconnects using metal (e.g., copper) wiring in the package substrate 112. Adjacent packages 110 can also be connected with interconnect path 122. For example, interconnect path 122 may proceed through the module substrate 102, or even through an interfacing bar (e.g., chiplet) within the module substrate 102. Likewise, connection may be with electrical interconnects within wiring in the module substrate 102 or interfacing bar therein. In other embodiments, the interconnect path 122 and/or interconnect path 120 can be an optical path as described herein. Furthermore, dies 114 from the different packages 110 can be coupled using an optical interconnect path 124, which can proceed through the module substrate 102 or through one or more optical communication bars described herein. Connectors 240 may also be integrated for the option of external optical interconnect paths 124.

In accordance with embodiments, the interconnect paths 120, 122, 124 can optionally be optical paths, particularly as distance increased above a nominal amount. In the following description, various optical interconnect paths can be generally referred to as optical paths 125 supported for example by waveguides, fiber bundles, etc. As will become apparent in the following description, the optical paths in accordance with embodiments can vary between short and extra-long reach applications. Thus, the paths can be intra-chip, inter-chip, intra-package, inter-package, intra-module, and inter-module with varying distances between modules, such as rack-to-rack or longer. In some embodiments the optical paths can be integrated into optical communication bars, which can be chiplet-sized or interposer sized. The optical communication bars can be placed onto other routing substrates, integrated into routing substrates, or be routing substrates such as an interposer. The optical paths can also be formed at wafer-level or panel-level, and singulated as distinct optical communication bars or interposers. The optical paths can also be integrated at wafer-level or panel-level, such as with fanout routing. Dies 114 may be the same or different.

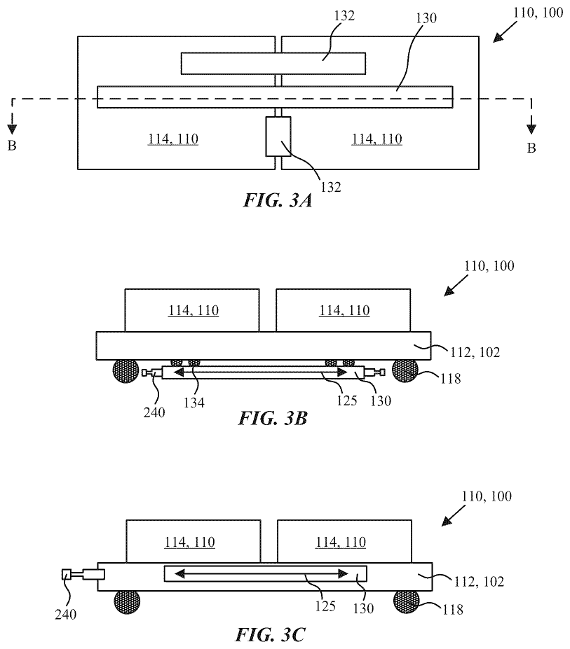

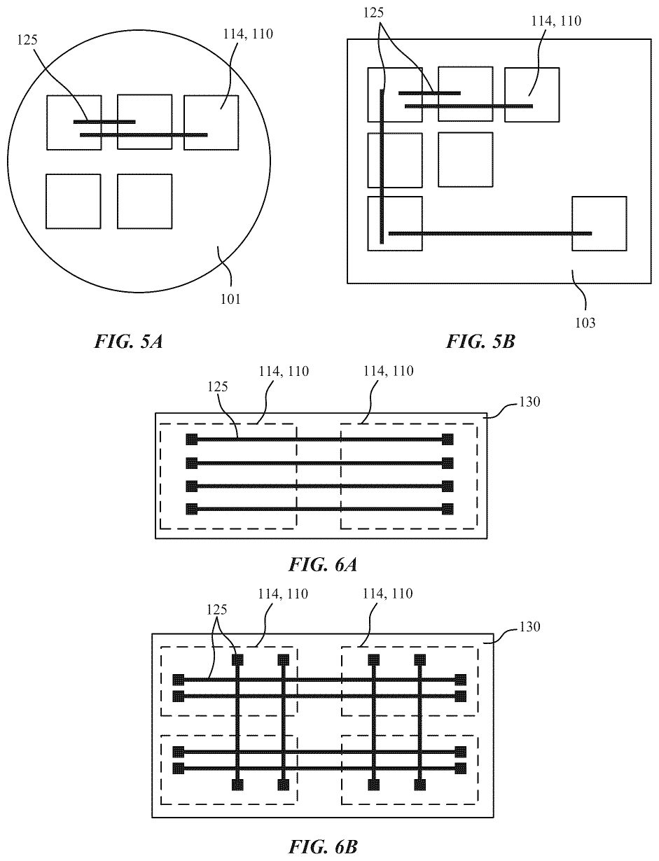

Referring now to FIGS. 3A-3C, FIG. 3A is a schematic top view illustration of a 3D electronic assembly with a combination of electrical and optical communication bars in accordance with an embodiment; FIGS. 3B-3C are schematic cross-sectional side view illustrations of 3D electronic assemblies along section B-B of FIG. 3A in accordance with embodiment. As shown, the electronic assemblies can be either a package 110 or module 100, for example similar to that illustrated in FIGS. 2A-2B. It is however to be appreciated that such schematic illustrations are merely exemplary and other configurations are contemplated in accordance with embodiments. In the particular 3D embodiment illustrated, the optical communication bar 130 can be arranged underneath the dies 114 or packages 110. In the embodiment illustrated in FIG. 5B the dies 114 or packages 110 can be electrically connected to the package substrate 112 or module substrate 102, for example with solder bumps, hybrid bonding, or forming the package substrate 112 over the molded dies 114. Likewise, the optical communication bar 130 can be electrically connected to the package substrate 112 or module substrate 102, for example, with solder bumps 134, hybrid bonding, or forming the package substrate 112 over a molded optical communication bar 130. In the embodiment illustrated in FIG. 3C the optical communication bar 130 can be embedded within the package substrate 112 or module substrate 112. In both configurations, the optical path extends through the optical communication bar 130. Such a 3D configuration can reduce the package or module footprint (area) and support high bandwidths, though may be exposed to heat due to thermal path to the dies 114 or packages 110. As shown, in FIG. 3A various electrical interfacing bars 132 (e.g., chiplets) can be located adjacent to the optical communication bar 130 to support shorter die-to-die electrical interconnection paths. Connectors 240 may also be integrated for the option of external optical interconnect paths 125. The optical communication bars 130 in accordance with embodiments also include electrical connections similar to the electrical interfacing bars 132, and thus provide both optical and electrical communication paths. In many embodiments the optical communication bards 130 and electrical interfacing bars 132 can be chiplet-like, for example where they do not fill or cover an entire substrate/interposer areas for cost or other reasons. Multiple types of bars may be possible.

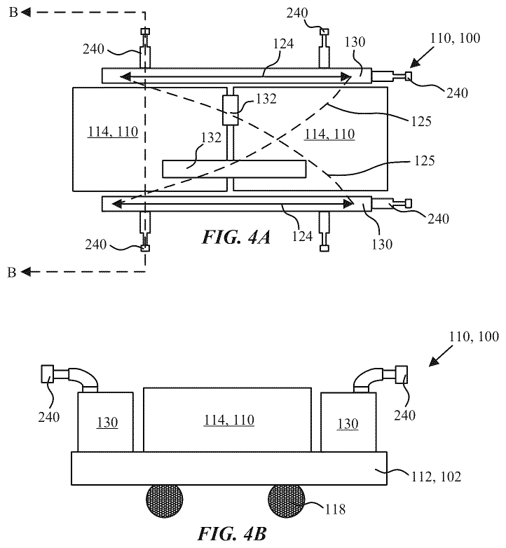

Referring now to FIGS. 4A-4B, FIG. 4A is a schematic top view illustration of a side-by-side electronic assembly with a combination of electrical and optical communication bars in accordance with an embodiment; FIG. 4B is a schematic cross-sectional side view illustration of a side-by-side electronic assembly along section B-B of FIG. 4A in accordance with an embodiment. As shown, the electronic assemblies can be either a package 110 or module 100, for example similar to that illustrated in FIGS. 2A-2B. It is however to be appreciated that such schematic illustrations are merely exemplary and other configurations are contemplated in accordance with embodiments. In the particular side-by-side embodiment illustrated, the optical communication bar 130 can be arranged side-by-side, and laterally adjacent to the dies 114 or packages 110. In this manner, the dies 114 or packages 110 can be electrically connected to the package substrate 112 or module substrate 102, for example with solder bumps, hybrid bonding, or forming the package substrate 112 over the molded dies 114. Likewise, the optical communication bar 130 can be electrically connected to the package substrate 112 or module substrate 102, for example, with solder bumps, hybrid bonding, or forming the package substrate 112 over a molded optical communication bar 130 and dies. In such configurations, the optical path extends through the optical communication bar 130. Such a side-by-side configuration may have a larger footprint (area) compared to a 3D configuration, though more volume can be used to integrate the optical components and the optical communication bar(s) 130 can be cooler due to no direct thermal path between the dies 114 or packages 110 and the optical communication bar(s) 130. As shown, in FIG. 4A various electrical interfacing bars 132 (e.g., chiplets) can still be provided underneath the dies 114 or packages 110 to support shorter die-to-die electrical interconnection paths. Connectors 240 may also be integrated for the option of external optical interconnect paths 125.

As described above the optical paths 125 can be formed at wafer-level or panel-level, and singulated as distinct optical communication bars or interposers. The optical paths can also be integrated at wafer-level or panel-level, such as with fanout routing. Referring to FIGS. 5A-5B, FIG. 5A is a schematic top plan view illustration of a plurality of optical paths 125 formed across a wafer 101 in accordance with an embodiment; FIG. 5B is a schematic top plan view illustration of a plurality of optical paths formed across a panel 103 in accordance with an embodiment. Wafer-level or panel-level integration can allow for harvesting of select areas or sized optical communication bars, interposers, etc. For example, wafer 101 may be device wafers or fanout reconstituted wafers. Furthermore, panel integration can be even larger than wafer size such as 500×500 mm, 1,000×1,000 mm or larger. In the exemplary embodiments shown in FIGS. 5A-5B the optical paths 125 can be formed across dies 114 (either reserved die areas at wafer/panel level, or reconstituted dies) or packages 110. Various die or package sets with optical paths can then be singulated. Alternatively, distinct optical communication bars or interposers can be singulated, where the harvest communication bars or interposers have optical paths and connections for bonding with a pre-determined die/package set. A variety of integration techniques can be utilized for the optical paths, such as flip chip mounting of optical communication bars or the formation of a large-area interposer layer than can then be diced.

Wafer-level and panel-level packaging techniques can also be utilized to harvest optical communication bars 130 (including interposers) of various sizes and routing directions. FIG. 6A is a schematic top plan view illustration of an optical communication bar 130 including linear optical paths 125 in accordance with an embodiment. As shown, the optical paths 125 can connect between multiple dies 114 or packages 110. FIG. 6B is a schematic top plan view illustration of an optical communication bar 130 including gridded optical paths in accordance with an embodiment. As shown, the optical paths 125 can be multi-directional, for example, including X, Y, and Z optical routing. The optical communication bars 130 shown in FIGS. 6A-6B can be discrete “bars” coupling multiple electronic components, or full interposers.

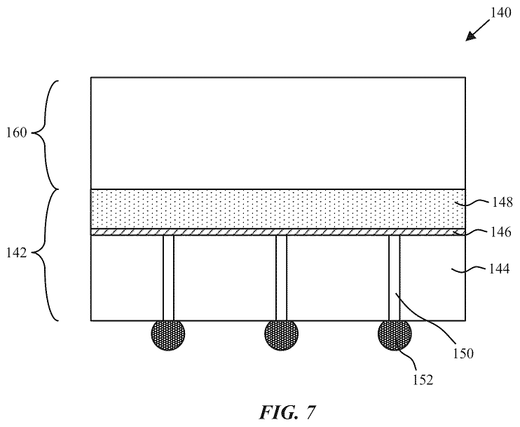

The optical communication bars may include photonic waveguides or photonic wires, for example, coupled with optical engines that include one or more converters such as electrical-to-optical (EO) converters and optical-to-electrical (OE) converters and controller logic (also referred to as conversion electronics). FIG. 7 is a schematic cross-sectional side view illustration of an optical engine 140 in accordance with an embodiment. As shown, the optical engine can include both controller logic 142 and converter(s) 160. The converters 160 can be EO converters, OE converters, or a combination of both. An EO converter may include any suitable optical transmitter such as laser, light emitting diode, or other light source and modulator. An OE converter May include an optical receiver such as a photodetector (avalanche photodiode, p-i-n photodiode, etc.). The controller logic 142 can include the necessary driving circuitry for the converter(s), and can optionally include additional components such as multiplexers, demultiplexers, modulators, buffers, etc. which may depend upon the type of optical transmitter or receiver used, bandwidth requirements, etc.

The optical engines 140 in accordance with embodiments can be fabricated using wafer-on-wafer (WoW), chip-on-wafer (CoW), flip chip, or other fabrication sequences for example. For both WoW and CoW the converter(s) 160 can be hybrid bonded or solder bonded to the controller logic 142 for example. An array of optical engines 140 can then be singulated from a single wafer. In the particular embodiment illustrated, the controller logic 142 may include a semiconductor substrate 144, a plurality of through vias 150 (e.g., through silicon vias) for back side electrical connection, where a plurality of solder bumps 152 may be placed. A device layer 146 can be located over the semiconductor substrate 144 to support the specific controller logic, including necessary driving circuitry for the converter(s), and optionally additional components such as multiplexers, demultiplexers, modulators, buffers, amplifiers, receivers, drivers, etc. The device layer 146 may be an epitaxial layer including various doped regions and devices (e.g., transistors, etc.) formed thereon. A back-end-of-the-line (BEOL) build-up structure 148 including various metal wiring layers, vias, and dielectric layers can then be formed over the device layer 146. The converter(s) 160 can be joined with the BEOL build-up structure 148.

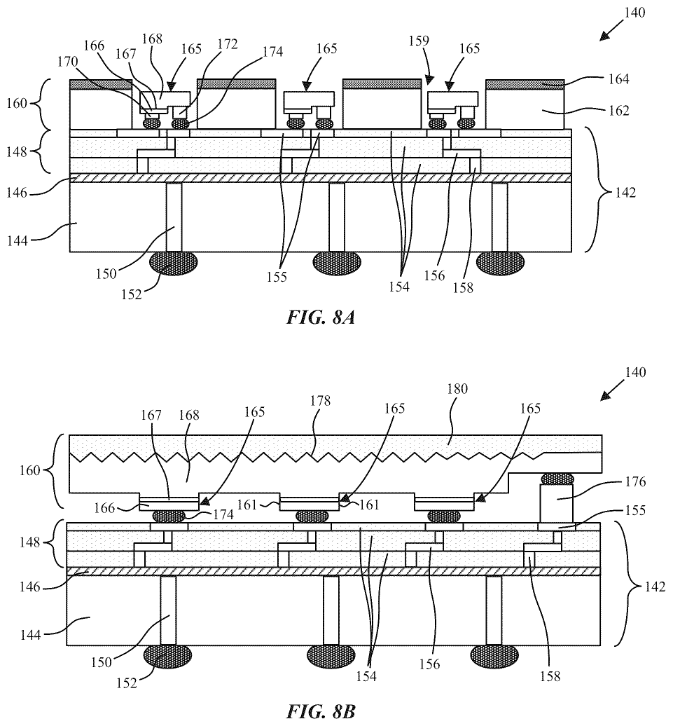

FIG. 8A is a schematic cross-sectional side view illustration of an optical engine 140 including a plurality of discrete diodes 165 accordance with an embodiment. The controller logic 142 may be fabricated similarly as described with regard to FIG. 7 including a semiconductor substrate 144, a plurality of through vias 150 (e.g., through silicon vias) for back side electrical connection, device layer 146, and (BEOL build-up structure 148 including various metal wiring layers 156, vias 158, and dielectric layers 154, terminating with landing pads 155. In the particular embodiment illustrated, a bank layer 162 and black matrix layer 164 can be formed over the BEOL build-up structure 148 followed by patterning to form a plurality of bank openings 159 exposing the landing pads 155. An array of discrete diodes 165 can then be mounted on the landing pads 155 within the bank openings 159, with the bank layer providing optical isolation between the diodes 165. For an EO converter the diodes 165 can be any optical emitter such as laser, light emitting diode (LED). Other light sources can also be used for the emitters. For OE converters the diodes 165 can be avalanche photodiodes, p-i-n photodiodes, etc. In some embodiments, the diode can be a micro diode with a maximum width of less than 100 μm, a nano LED with maximum width of less than 1 μm, VCSEL or other OE. In the exemplary illustration the emitters/detectors can be horizontal diodes including a top doped layer 168 of first dopant type (e.g., n-type), a bottom doped layer 166 of second dopant type opposite the first dopant type (e.g., p-type), and an active layer 167 therebetween. For example, the active layer 167 can include one or more quantum well layers and dielectric barrier layers. Electrical contacts 170 and 172 can be made with the bottom doped layer 166 and the top doped layer 168, respectively. The electrical contacts 170, 172 can be bonded to the landing pads 155 with solder bumps 174, for example. It is to be appreciated that while horizontal diodes are illustrated that the emitter/detector structure can also be vertical diodes, as well as various laser or other emitter/detector structures.

FIG. 8B is a schematic cross-sectional side view illustration of an optical engine including a plurality of joined diodes accordance with an embodiment. In the particular embodiment illustrated, the diodes 165 are formed by etching an array of mesa structures into a p-n diode layer (or similar) to form mesa sidewalls 161 extending through the bottom doped layer 166 and active layer 167. A shared top doped layer 168 may span across and join all the mesa structures together. As shown, a roughened surface 178 m ay optionally be formed for light extraction for optical emitters, followed by a transparent planarization layer 180. As shown, the bottom doped layers 166 and top doped layer 168 can be electrically connected with the BEOL build-up structure 148 contact pads 155 with solder bumps 174, and optional bond post 176. It is to be appreciated that while joined diodes are illustrated as p-n diodes that the emitter/detector structure can also be various laser or other emitter/detector structures.

It is to be appreciated that the exemplary embodiments shown in FIGS. 8A-8B are merely examples of types of converters 160 structures that can be integrated into the optical engines 140. It is to be appreciated that a variety of alternative converter structures and processing techniques can be used, such as organic light emitting diodes (OLEDs) for the EO converters. Furthermore, the optical engines 140 can be strictly EO, strictly OE, or a combination of EO and OE. In some embodiments the optical engine can include an inorganic semiconductor based LED or vertical-cavity surface-emitting laser (VCSEL), such as a GaN based micro LED or nano LED for EO, and a silicon photodetector for OE. For example, an OLED EO may be a slower, less efficient EO option, while the silicon photodetector provides high sensitivity (e.g., avalanche photodiode, photon avalanche photodiode, silicon photomultiplier). Inorganic semiconductor-based LEDs or VCSELS may be used for faster and longer reach EO options. Optical engines 140 may be provided at opposite ends of the optical communication bars 130 and connected with a large number of optical paths (e.g., in the tens to hundreds of thousands) to support tens of thousands to millions of channels. While the illustrative examples shown in FIGS. 8A-8B are focused on EO optical engines, the optical engines may also, or alternatively, include photodiodes (e.g., avalanche photo diode, single photon avalanche diode (SPAD), or other enhanced PD using light trapping, charge focusing, advanced materials (e.g., black silicon, micro texturing)) as diodes 165 and a transimpedance amplifier within the controller logic 142.

Embodiments describe electronic assemblies in which one or more optical communication bars are integrated to provide an optical path across a single die or package, or between multiple dies or packages. The optical communication bars can be rigid or flexible. Connectors can be integrated with the optical communication bars for longer reach applications. In the following description various electronic assemblies are described and illustrated including different optical paths, connection methods and fabrication techniques. It is to be appreciated that a lot of the optical links goes into optical connectors, alignment, etc. here the optical paths are registered in some automated fashion, such as lithography or additive manufacturing and only coarser connection are made electrically, such as with micro bumps. The optical communication bars can be waveguide rich, keeping the link data rate moderate.

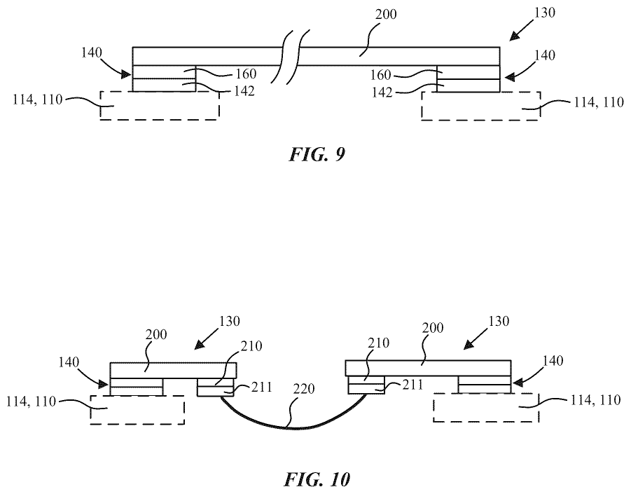

FIG. 9 is a schematic cross-sectional side view illustration of an optical communication bar 130 with a wholly contained optical path in accordance with an embodiment. As shown the optical communication bar 130 can include a pair of optical engines 140 each including an EO converter and/or OE converter for optical transceiver and/or receiver, respectively. The pair of optical engines 140 may be coupled with a solid or flexible waveguide 200. The pair of optical engines can be further electrically connected with respective dies 114 or packages 110 using suitable techniques such as micro bump, hybrid bonding, connector, etc. In an embodiment, an optical communication bar 130 can be used for massively parallel image communication in which a large number of channels can be formed in the waveguide using lithography, nano-imprinting, optical fibers, etc. The image can be “I/O” black or weight, gray (pulse-amplitude modulation) or color (wavelength division multiplexing) or pulse-amplitude modulation and wavelength division multiplexing with corresponding complexity in the sensor for faster data rate.

FIG. 10 is a schematic cross-sectional side view illustration of an optical path spanning between multiple optical communication bars 130 in accordance with an embodiment. As shown, the optical communication bars 130 can each include an optical engine each including an EO converter and/or OE converter for optical transceiver and/or receiver, respectively. The optical engine 140 may be coupled with a solid or flexible waveguide 200, which is also coupled with a connector 210. A second waveguide 220, such as a fiber bundle, can include connectors 211 coupled with the connectors 210 of multiple optical engines 140. Connectors 210, 211 can be any suitable type depending upon application, such as lucent connectors (LC), standard connectors (SC), ST connectors, ferrule core (FC) connectors, multi-position optical (MPO) connectors, MT-RJ connectors, etc. Such a configuration can support both within module/die or external communication.

The photonic waveguides can be formed using a variety of suitable techniques and may include photonic wires (e.g., formed using 3D multi-photon write, holographic write, micro-pen write, direct optical wire bonding, or a mix), or index defined patterns forms using techniques such as nano imprint (embossing), lithography, etc. Additional optics for coupling the optical transceivers (emitters) and optical receivers (detectors) with the photonic waveguides, such as lenses, grating couplers, mirrors, prisms, optical vias, etc. can also be formed using similar techniques.

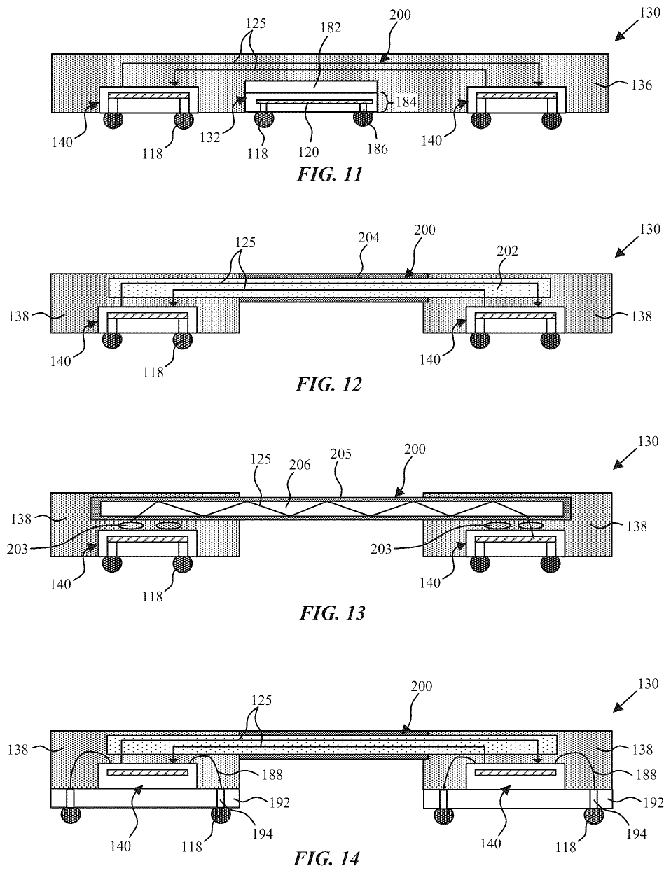

FIG. 11 is a schematic cross-sectional side view illustration of an optical communication bar including optical and electrical interconnect paths in accordance with an embodiment. In the particular embodiment illustrated, the optical communication bar 130 can include a pair of optical engines 140 connected with a waveguide to provide optical path(s) 125 therebetween, as well as one or more interfacing bars 132 to provide a shorter-range electrical interconnect path 120 across longitudinal length of the interfacing bar 132. In an exemplary embodiment the interfacing bar 132 can include a substrate 182 such as semiconductor (e.g., silicon), glass, etc. and a build-up structure 184 formed over the substrate 182. The build-up structure 184 can be a common routing structure including metal wiring layers, dielectric layers, vias 186, etc. through which the electrical interconnect path 120 spans. Each of the optical engines 140 and interfacing bar(s) 132 can be embedded in a molding compound layer 136, or other suitable gap fill material. As such, the optical communication bar 130 may be rigid. Solder bumps 118 may optionally be placed onto the optical communication bar 130 for electrical connection, though the interfacing bar can also be connected using other suitable techniques, such as hybrid bonding, anisotropic conductive film (ACF), and optical.

FIG. 12 is a schematic cross-sectional side view illustration of an optical communication bar 130 including a waveguide 200 and flexible encapsulation in accordance with an embodiment. In such an embodiment, the optical engines 140 can be separately embedded in molding compound layers 138. Likewise, the waveguide 200 can be partially embedded in the molding compound layers 138 and include optical layers 202 surrounded by a flexible housing 204 spanning between the molding compound layers 138. Portions of flexible housing 204 may additionally be embedded in the molding compound layers 138.

FIG. 13 is a schematic cross-sectional side view illustration of an optical communication bar 130 including a holographic waveguide 200 and flexible encapsulation in accordance with an embodiment. FIG. 13 is substantially similar to that of FIG. 12, with a holographic waveguide including a core 206 surrounded by flexible cladding 205. Additionally, micro-lenses (holographic) 203 can be located between the holographic waveguide 200 and optical engines 140.

While the optical engines 140 described to this point may include vertically stacked components with through vias, this is not a requirement. FIG. 14 is a schematic cross-sectional side view illustration of an optical communication bar including wire bonded optical engines in accordance with an embodiment. As shown, one or more of the components of the optical engine 140 can be placed onto a routing substrate 192 and electrically connected to the routing substrate 192 with wire bonds 188. Vertical electrical paths 194 can additionally provide back side connection for the optical engines 140.

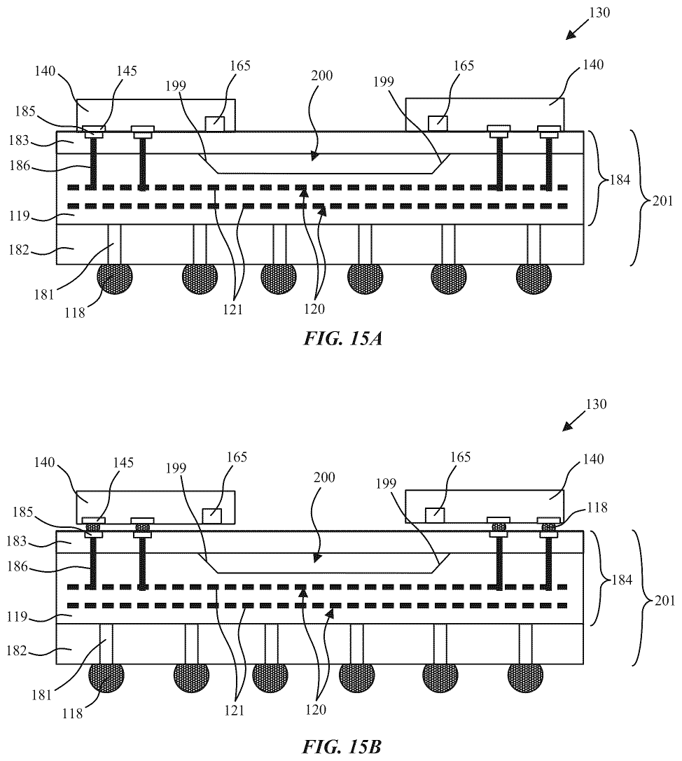

The optical communication bars 130 in accordance with embodiments can also be interposer or chiplet-based, where the optical engines are connected to a waveguide within a separately formed interfacing bar. Referring to FIGS. 15A-15B, FIG. 15A is schematic cross-sectional side view illustration of an optical communication bar including optical engines hybrid bonded to an interfacing bar in accordance with an embodiment; FIG. 15B is schematic cross-sectional side view illustration of an optical communication bar including optical engines flip chip bonded to an interfacing bar in accordance with an embodiment. As shown in FIGS. 15A-15B, the interfacing bar 201 can optionally include both electrical and optical function. In the particular embodiment illustrated the interfacing bar 201 can optionally include a base substrate 182 such as semiconductor (e.g., silicon), glass, etc. to provide structural support and a build-up structure 184 which can include waveguide 200 as well as optional electrical function. For example, the build-up structure 184 can include a plurality of dielectric layers 119 such as oxides, nitrides, polymers, etc. and metal routing layers 121 and vias 186 to form electrical interconnect paths 120. The base substrate 182 may additionally include a plurality of through vias 181 (e.g., through silicon vias, through glass vias, etc.) for back side connection with solder bumps 118. Where the interfacing bar 201 is flexible the base substrate 182 may optionally be omitted or formed of a flexible material.

The waveguide 200 and mirrors 199 may be formed using a variety of techniques such as ion beam, laser etch, anisotropic etch, nano imprint, etc. In an embodiment, the waveguides and mirrors are formed using nano imprint, which is an embossing/stamping technique where the pattern of the waveguide 200 is embossed/stamped into a dielectric layer 119 (e.g., an oxide layer) of the build-up structure 184, and the cavity is then filled with a polymer or other dielectric material (e.g., and oxide) with different refractive index than the dielectric layer 119. A cladding layer 183 and optional micro lenses (or grating or appropriate coupler) may then be formed over the waveguide 200 for optical coupling with the optical engines 140, which can then be provided using hybrid bonding (FIG. 15A) or flip chip (FIG. 15B). Where hybrid bonding is utilized the cladding layer 183 and contact pads 185 can be hybrid bonded with the optical engines 140, including a dielectric hybrid bonding surface and contact pads 145. As shown, diodes 165 of the optical engines 140 can be aligned with the waveguide (and optional micro lenses, grating, or appropriate coupler) for either light transmission or reception.

It is to be appreciated that while the illustrations provided for FIGS. 15A-15B resemble a die-last manufacturing sequence in which the optical engines 140 are bonded to an interfacing bar 201, that similar assemblies can be manufactured with a die-first manufacturing sequence in which the interfacing bars are bonded to the optical engines, or instead formed on top of the optical engines, for example if embedded in a gap fill material (e.g., molding compound, etc.).

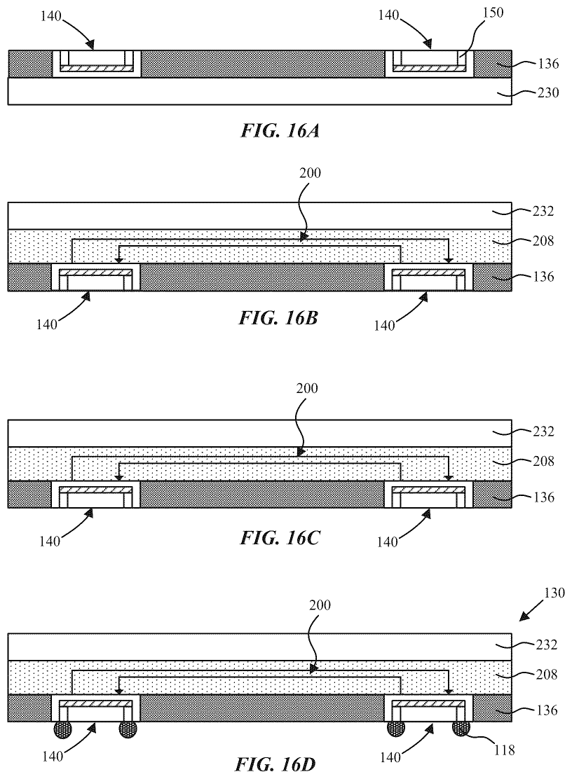

Referring now to FIGS. 16A-16D, cross-sectional side view illustrations are provided for a sequence of forming a waveguide over embedded optical engines in accordance with an embodiment. As shown in FIG. 16A the sequence may begin with mounting the optical engines 140 face down onto a carrier substrate 230. This may be followed by encapsulating the optical engines 140 in a molding compound layer 136, followed by an optional grinding operation to level the surface, and optionally expose vias 150. The carrier substrate 230 can then be removed followed by formation of a waveguide 200. For example, this may be accomplished for the formation of a suitable dielectric layer 208, followed by nano imprinting lenses and the waveguide 200 as shown in FIG. 16B. If required, this may include many layers. An encapsulation layer 232 can then be formed over the waveguide 200 as shown in FIG. 16C, followed by application of an optional redistribution layer as required, and solder bumps 118 as shown in FIG. 16D. Multiple optical communication bars 130 can then be scribed from a single stack-up. If the waveguides 200 and dielectric layer(s) 208 are made sufficiently thin, or of suitable materials such as polymer and the optical engines 140 are appropriately molded, such a configuration can also support flexibility.

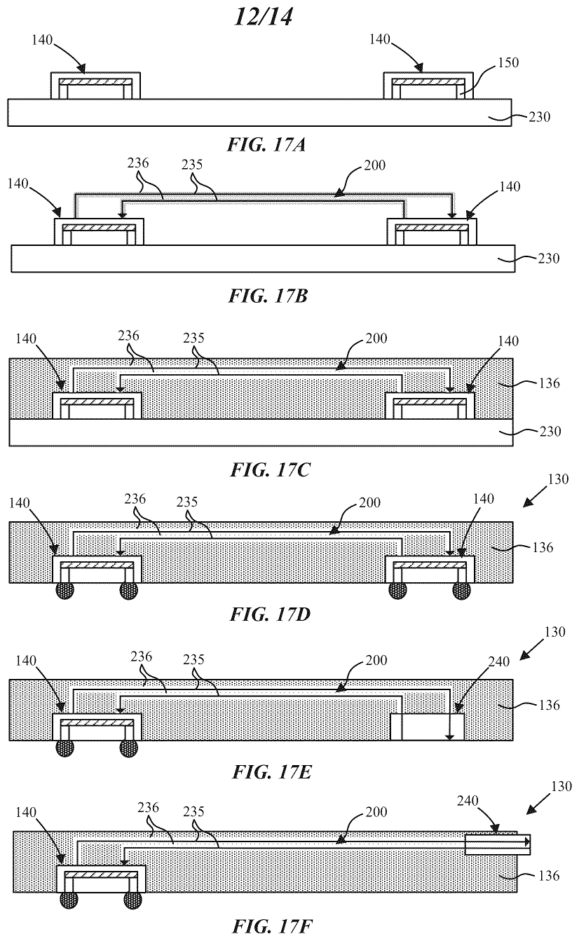

Referring now to FIGS. 17A-17F cross-sectional side view illustrations are provided for sequences of forming waveguides over optical engines and embedding both in accordance with embodiments. As shown in FIG. 17A the sequence may begin with mounting the optical engines 140 face down onto a carrier substrate 230. This can be followed by formation of the waveguide 200 cores 235 as shown in FIG. 17B. In accordance with embodiments this may be accomplished using suitable techniques such as 3D multi-photon write, holographic write, micro pen, or a mixture thereof. While not separately illustrated, a 3D multi-photon write process may include first depositing a layer of photoresist, followed by using two-photon lithography to define the shape of the cores 235 (also referred to as photonic wire bond waveguides), and the removal of the unexposed photoresist in a development operation. A cladding 236 (e.g., low index material) can also be optionally dispensed over the cores 235 (e.g., high index material), where it spreads to form a thin coating, completing the waveguides 200. In such embodiments the cores 235 can be formed in alignment with the diodes of the optical engines 140. In such a process, since the shape of the cores (photonic wire bond waveguides) can be adapted to positions of the coupling interfaces, high-precision alignment of the optical engines 140 becomes obsolete. Moreover, by using tapered freeform waveguides, the cores 235 can cope with vastly different mode fields of the devices to be optically connected. This technique can be fully automated and can be suitable for high-throughput mass production. The waveguides 200 and optical engines 140 can then be encapsulated together in the same molding compound layer 136 as shown in FIG. 17C, followed by removal of the carrier substrate 230, formation of optional redistribution layer and solder bumps 118 as shown in FIG. 17D.

Referring now to FIGS. 17E-17F variations of the structure of FIG. 17D are shown including connectors 240. Connectors 210, 211 can be any suitable type depending upon application, such as lucent connectors (LC), standard connectors (SC), ST connectors, ferrule core (FC) connectors, multi-position optical (MPO) connectors, MT-RJ connectors, etc. As shown, rather than including a pair of optical engines 140, the optical communication bar 130 can include a waveguide 200 that is coupled to an optical engine 140 at one end and a connector 240 at an opposite end. In this manner, the optical communication bar 130 can be connected to an additional optical path (e.g., cable, etc.) for longer reach assemblies. In the embodiment illustrated in FIG. 17E the connector 240 is co-located along a same surface as the optical engine 140 electrical connection with solder bumps 118. In the embodiment illustrated in FIG. 17F connector 240 is located along a side edge of the optical communication bar 130 for lateral optical connection rather than vertical optical connection.

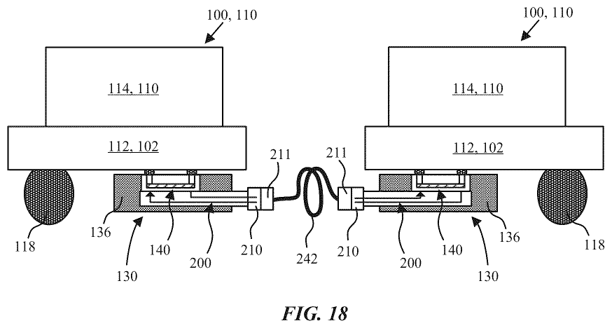

Connectors may be used for longer reach applications, for example for package-to-package and module-to-module connection. FIG. 18 is a schematic cross-sectional side view illustration of an electronic system including optical communication bars with connectors for external optical communication in accordance with an embodiment. In the particular embodiment illustrated optical communication bars 130 are used for package-to-package or module-to-module connection. As shown, each module 100 (or package 110) can include a routing substrate such as a module substrate 102 or package substrate 112 onto which a corresponding optical communication bar 130 is mounted or otherwise connected. Each optical communication bar can include an optical engine 140, waveguide 200 and connector 210. The particular arrangement could be any optical communication bar 130 described herein, as well as other configurations. As shown, the optical engine 140 and waveguide 200 can be embedded within a molding compound layer 136, though this is merely exemplary, and embodiments are not so limited. As shown, a fiber bundle 242 (or ribbon) can include connectors 211 coupled with the connectors 210 of the corresponding modules 100 for optical connection. In the particular embodiment illustrated, the optical communication bars 130 are integrated in a 3D configuration, below the dies 114 or packages 110, for example for core-to-core optical connection. In this manner, signals do not need to come to die/package edges before being converted to optical. This can save energy and latency. Exemplary applications include at least core-to-core optical connection across modules 100 (e.g., cards in data center).

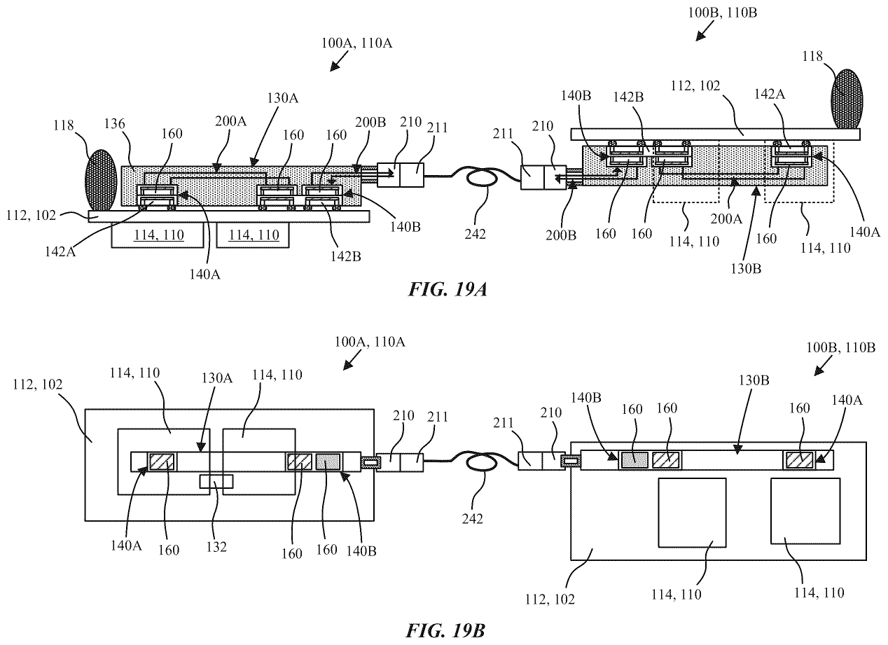

FIGS. 19A-19B are schematic cross-sectional side view and top view illustrations of electronic systems with optical communication bars including optical engines for short reach optical communication and connectors for external optical communication in accordance with embodiments. In each of the embodiments illustrated both 3D and side-by-side optical communication bar configurations are shown for the modules 100A, 100B, though it is to be appreciated that this is for illustrational purposes rather than restrictive purposes. The embodiments illustrated in FIGS. 19A-19B are share similarities to that illustrated in FIG. 18, such as the optical communication bars 130A, 130B including connectors 210 for optical coupling between modules 100A, 100B. In the particular embodiments illustrated the modules 100A (or packages 110A) on the left side are shown with 3D optical paths in which the optical communication bars 130A is vertically oriented with dies 114 or packages 110 within a corresponding module 100A, while the modules 100B (or packages 110B) on the right side are shown with side-by-side optical paths in which the optical communication bar 130B is mounted side-by-side with the dies 114 or packages 110 within a corresponding module 100B. It is to be appreciated that the particular configurations are provided for illustrational purposes only, and it is not required that a module with a 3D orientation is connected with a module including a side-by-side orientation. A variety of configurations are envisioned.

In the particular embodiment illustrated the optical communication bards can include waveguides 200A for communication between optical engines 140A, 140B within the same optical communication bar, as well as waveguides 200B that are coupled with connectors 210 for module-to-module connection. The optical engines, and more particularly the controller logic 142A, 142B and converters 160 can be designed differently depending upon the optical path distances and profiles (e.g., connectors, waveguide count, etc.). For example, the converters 160 for the shorter optical paths between optical engines 140A-140B can have micro LED or nano LED electrical-to-optical converter 160, and p-i-n photodiodes for the optical-to-electrical converter 160. This may support moderate speeds such as 10 Gbps, and relatively wider optical paths in the waveguide 200A. The converters 160 for the longer optical paths between optical engines 140B-140B in modules 100A, 100B can have laser diodes in the electrical-to-optical converter 160, and p-i-n photodiodes for the optical-to-electrical converter 160. Furthermore, the controller logic 142B can include modulators, multiplexers (e.g., wavelength division multiplexers) and demultiplexers to support higher speed transmission, such as 25-224 (or state of the art) Gbps. Furthermore, the optical paths in the waveguide 200B can have relatively narrower widths and pitch. In some embodiments the fiber bundle 242 (or ribbon) can provide connections within a rack, span rack-to-rack, across a datacenter, or for telecom distances. Configurations such as those shown in FIGS. 19A-19B can span distances greater than 10 meters for example.

In utilizing the various aspects of the embodiments, it would become apparent to one skilled in the art that combinations or variations of the above embodiments are possible for forming an electronic assembly with optical communication bar. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. An electronic assembly comprising:
a first die including a first core region;
a second die including a second core region;
an optical communication bar providing an optical path between the first core region and the second core region.

2. The electronic assembly of claim 1, wherein:
the first die and the second die are located on a top side of a routing layer; and
the optical communication bar is located on a bottom side of the routing layer.

3. The electronic assembly of claim 1, wherein:
the first die, the second die, and the optical communication bar are on a top side of a routing layer.

4. The electronic assembly of claim 1, wherein the optical communication bar includes:
a first optical engine including a first controller logic and a first optical transmitter;
a second optical engine including a second controller logic and a second optical detector;
one or more molding compound layers encapsulating the first optical engine, the second optical engine, and the optical path;
wherein the optical path extends between the first optical transmitter and the second optical detector.

5. The electronic assembly of claim 4, wherein the one or more molding compound layers comprises a first molding compound layer encapsulating the first optical engine, and a second molding compound layer encapsulating the second optical engine.

6. The electronic assembly of claim 5, wherein the optical path extends through a flexible housing that spans between the first molding compound layer and the second molding compound layer.

7. The electronic assembly of claim 4, wherein the one or more molding compound layers is a single molding compound layer encapsulating the first optical engine, the second optical engine, and the optical path.

8. The electronic assembly of claim 7, further comprising an electrical interfacing bars embedded in the single molding compound layer to provide electrical die-to-die routing.

9. The electronic assembly of claim 8, wherein the electrical die-to-die routing is between the first die and the second die.

10. The electronic assembly of claim 4, wherein the first optical engine and the second optical engine are mounted onto an interfacing bar including a waveguide.

11. The electronic assembly of claim 4, wherein the first optical transmitter is bonded on top of the first controller logic.

12. The electronic assembly of claim 11, wherein the first optical transmitter is hybrid bonded to the first controller logic.

13. The electronic assembly of claim 12, wherein the second optical detector is hybrid bonded to the second controller logic.

14. The electronic assembly of claim 1, further comprising a second optical path between the first die and a connector for external optical connection with the electronic assembly.

15. An electronic system comprising:
a first electronic assembly including a first routing substrate and a first optical communication bar connected with the first routing substrate, wherein the first optical communication bar comprises:
a first optical engine;
a first waveguide; and
a first connector coupled with the first waveguide;
a second electronic assembly including a second routing substrate and a second optical communication bar connected with the second routing substrate, wherein the second optical communication bar comprises:
a second optical engine;
a second waveguide; and
a second connector coupled with the second waveguide;
a fiber bundle coupled with the first connector and the second connector.

16. The electronic system of claim 15, further comprising a first die and a second die connected with the first routing substrate.

17. The electronic system of claim 16, wherein the first optical communication bar includes a local waveguide connected between the first die and the second die.

18. The electronic system of claim 17, wherein the first optical communication bar includes:
a first internal optical-to-electrical (OE) converter coupled with the local waveguide;
a first internal electrical-to-optical (EO) converter coupled with the local waveguide;
a first external EO converter coupled with the first waveguide;
wherein the first internal EO converter comprises a micro light emitting diode (LED) or nano LED, and the first external EO converter comprises a vertical-cavity surface-emitting laser (VCSEL).

19. The electronic system of claim 17, wherein the fiber bundle extends a longer distance than the local waveguide.
